(19) United States
(12) Patent Application Publication
(10) Pub. No.: US 2002/0141005 A1
(43) Pub. Date: Oct. 3, 2002

(54) Image processing program and image processing apparatus

(75) Inventors: Noriyuki Okisu, Osakasayama-Shi (JP); Masahito Niikawa, Sakai-Shi (JP)

Correspondence Address: SIDLEY AUSTIN BROWN & WOOD LLP, 717 NORTH HARWOOD, SUITE 3400, DALLAS, TX, 75201, US

(73) Assignee: MINOLTA CO., LTD.

(21) Appl. No.: 10/104,169

(22) Filed: Mar. 22, 2002

(30) Foreign Application Priority Data
Mar. 30, 2001 (JP) 2001-100063

(51) Int. Cl. G03F 3/08; H04N 1/46

(52) U.S. Cl. 358/540; 358/521

(57) ABSTRACT

It is an object of the present invention to subject an image file outputted from a digital camera to an adding process on a personal computer without deteriorating the image quality. An image processing program installed in a personal computer reads a plurality of original image data to which a γ correction process is effected in a digital camera, performs an inverse γ correction process on each image data and generates a plurality of linear image data. Further, after performing an interpolation process on each linear image data, it performs a synthesis process including an adding process to generate synthesized image data. The synthesized image data is subjected to a γ correction process and stored in a hard disk as a synthesize image file.

This application is based on application No. 2001-100063 filed in Japan, the contents of which are hereby incorporated by reference.

### BACKGROUND OF THE INVENTION

1. Field of the Invention

The present invention relates to a processing technique of image processing software for generating an image of high resolution, an image of widened gradation width and the like by synthesizing a plurality of images.

2. Description of the prior art

There has been a conventional technique in which an image of high quality is generated by capturing static images for plural times by means of an image capturing device such as digital camera and synthesizing data of the captured plurality of images.

(1) In Japanese Patent Application Laid-Open No.9-261526 discloses a technique wherein a precorrection is effected by additively synthesizing a plurality of images that have been continuously captured at such a short shutter speed that will not cause an influence of blur.

(2) Furthermore, Japanese Patent Application Laid-Open No.10-108057 discloses a technique that by synthesizing image data that has been obtained by capturing images while changing the focus position, image data wherein any subjects at different positions are in focus is generated.

(3) Further, U.S. Pat. No. 5,162,914 publication discloses a technique having a substantially widened dynamic range by capturing odd fields and even fields while changing the exposure time and synthesizing unblurred parts of these fields.

(4) Further, U.S. Pat. No. 5,402,171 publication discloses a technique which improves a resolution of an image by synthesizing an image from image data of four positions that are captured while moving the image the pickup device.

Furthermore, not only the above examples, techniques which bring out a variety of visual effects and realize improvement of image quality by synthesizing a plurality of static images have been put into practice.

Though these conventional techniques made it possible to obtain a variety of visual effects and improve image quality by such a synthesis process of plurality of images, however, they presume that the linearity is secured in the gradation characteristic of the image data to be synthesized.

In this connection, it has been known that a semiconductor image pickup device such as CCD or CMOS sensor provides excellent linearity of input/output characteristic. Therefore, there arises no problem in an image synthesis system which conducts a synthesis process while directly using the output data from a CCD.

To the contrary, in general digital cameras, analogue signals which are output data from a CCD are converted to digital signals in A/D conversion and γ correction for the digital signals is made in accordance with a display characteristic of a monitor of personal computer. That is, an image file outputted from the digital camera is a file that is outputted in the TIFF or JPEG form after being subjected to the γ correction process.

The image file thus outputted from the digital camera does not have a problem in terms of the linearity of input/output characteristic when viewed through a monitor of personal computer. However, the input/output characteristic of the image data that is stored as a file is nonlinear.

Therefore, it is intrinsically impossible to perform an adding process using image data that is captured by means of a general digital camera, and if a multiple synthesis process is forcefully executed, the gradation characteristic of the output image data would be out of order.

### SUMMARY OF THE INVENTION

The present invention is directed to a software product.

The present invention provides a program product in which a program which enables a data processing apparatus to execute a processing is recorded, the processing comprising the steps of: (a) reading a plurality of image data having been subjected to γ correction; (b) generating, with respect to each of the read image data, image data that have been subjected to a γ correction having a characteristic which is inverse to the γ correction effected on each of the read image data; and (c) generating synthesized image data resulting from synthesizing the generated plurality of image data.

According to this, since the plurality of image data to subjected to the γ correction are subjected to the γ correction having an inverse characteristic to the γ correction effected on each image data (inverse γ correction), and thereby synthesis process is achieved, it is possible to generate a synthesized image having high image quality.

Preferably, the image data having been subjected to the inverse γ correction is linear image data. According to this, since the synthesis process is conducted while imparting the linearity to the gradation characteristic by the inverse γ correction, it is possible to generate a synthesized image having high image quality without making the gradation characteristic out of order.

In another aspect of the present invention, the program product enables the further process of: performing a γ correction on the generated synthesized image data and generating image data in accordance with a display characteristic of an image display device.

According to this, the image file generated in accordance with the display characteristic of the image display apparatus is normally displayed on the image display apparatus such as personal computer monitor in the same manner as the normal image file.

In yet another aspect of the present invention, the step (c) includes the step of performing matching process between a plurality of linear image data.

According to this, by conducting synthesis process after performing registration for the plurality of image data to which linearity is imparted to their gradation characteristics by performing a matching process, it is possible to output synthesized image data of high image quality.

In a further aspect of the present invention, the γ correction process executed in the step (b) increases the number of gradation bits of the linear image data compared to that of the image data read in the step (a).

According to this, it is possible to perform the synthesis process in the area where the number of gradation bits exceeds that of the image file read in step (a).

In a further aspect of the present invention, the program product enables the further process of: performing an interpolation process of pixel with respect to each linear image data generated in the step (b).

According to this, it is possible to achieve a synthesis process of higher accuracy.

In a further aspect of the present invention, the process of the step (b) further comprises the process of: reading information regarding the γ correction that has been effected on the read image data from information associated with the image data read in step (a); and calculating a setting value of the γ correction having an inverse characteristic on the basis of the information regarding the γ correction.

In step (b), it is possible to reliably convert each read image data into the image data having a linearity.

In a further aspect of the present invention, the process of the step (b) further comprises the process of: performing a γ correction in accordance with a predetermined setting value when the information regarding the γ correction that has been effected on the read image data is not read from information associated with the image data read in step (a).

Even in the case where a γ correction setting information is not recorded in the tag information of the image data, it is possible to perform the inverse γ correction based on the default set γ value.

Furthermore, the present invention is directed to an image processing apparatus corresponding to the aforementioned software product.

Therefore, it is an object of the present invention to provide software which enables an adding process to be executed on a personal computer with respect to an image file outputted from a digital camera without deteriorating the image quality.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing a personal computer and a digital camera for performing an image processing.

FIG. 2 is a view showing a recording form of image file.

FIG. 3 is a view showing storage condition of image files managed for each folder.

FIG. 4 is a view showing a display characteristic of a display.

FIG. 5 is a view showing a characteristic of γ correction performed in the digital camera.

FIG. 6 is a block configurationally diagram of a personal computer.

FIG. 7 is a flow chart of a super-resolution process according to file designation.

FIG. 8 is a flow chart of a super-resolution process according to file designation.

FIG. 9 is a view showing a super-resolution process screen displayed on the display.

FIG. 10 is a view showing a file selecting screen.

FIG. 11 is a view showing a setting screen.

FIG. 12 is a view showing the super-resolution process screen during execution of the super-resolution process.

FIG. 13 is a view showing a result display screen of the super-resolution process.

FIG. 14 is a flow chart showing a super-resolution process according to batch process.

FIG. 15 is a flow chart showing a super-resolution process according to batch process.

FIG. 16 is a view showing a folder designating screen displayed on the display.

FIG. 17 is a view showing a γ function in which gradation bit number varies.

FIG. 18 is a view showing a registration process.

### DETAILED DESCRIPTION OF THE PREFERRED EMBODIMENTS

In the following, preferred embodiments of the present invention will be explained with reference to the drawings.

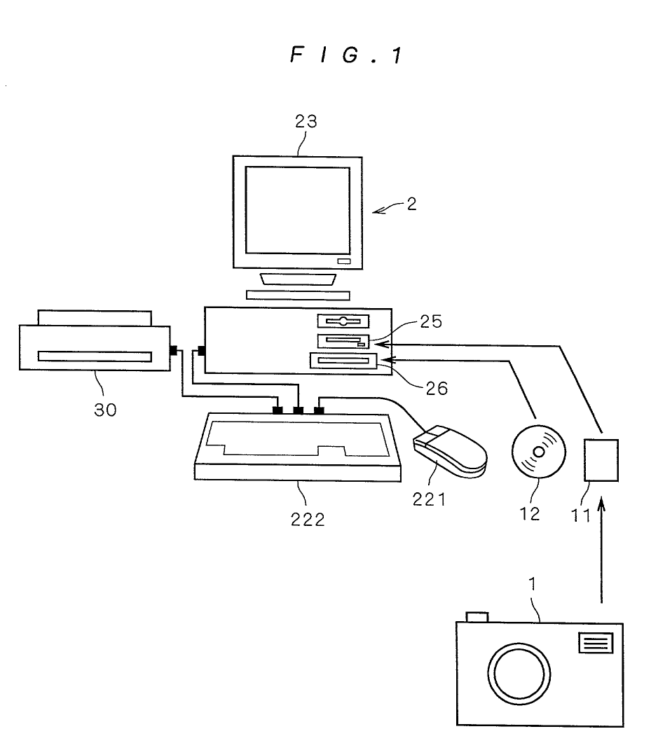

FIG. 1 shows a digital camera 1 and a personal computer 2 serving as a data processing apparatus for performing an image processing on image data captured in the digital camera 1.

Image data captured in the digital camera 1 is stored, for example, in a memory card 11. An operator pulls out the memory card 11 on which the image data is stored, and inserts it into a slot 25 provided in the personal computer 2. Then, the operator can view the image captured in the digital camera 1 by way of image software and the like operating on the personal computer 2. Also, it is possible to perform an image processing for the captured image by utilizing image processing software.

Also, the image data captured in the digital camera 1 may be transferred to the end of the personal computer 2 using a USB cable or the like. The image taken into the personal computer 2 can be checked on a display 23 and outputted to a printer 30 using image software.

{1. Image Data Generated by Exposures of Plural Times}

<1-1. Image Processing Mode>

The digital camera 1 has several exposure modes (hereinafter, referred to as image processing mode) presuming that a variety of image processings will be effected on an outputted image file.

“Image processing mode” refers to a mode in which a subject is continuously captured plural times while changing the exposure condition or without changing the exposure condition at the time of release, and a plurality of images captured in these exposures are respectively recorded on the memory card 11.

The plurality of captured images continuously captured in this mode are subjected to a predetermined image processing in an image processing apparatus such as personal computer 2 and synthesized for generating an image having a better image quality and visual effect than the original captured images.

The digital camera 1 according to the present preferred embodiment has image processing modes as follows: “blur adjusting mode”, “gradation adjusting mode”, “super-resolution mode” and the like. In the following, these three image processing modes will be briefly explained while exemplifying the case where one synthesized image data is generated from two captured images A and B for simplification.

“Blur adjusting mode” refers to an exposure mode in which two exposure operations are continuously made while changing the focal point at a single shutter operation, thereby obtaining a captured image A focusing on the main subject (for example, a person) and a captured image B focusing on the background of the main subject. In the subsequent image processing, these captured images A and B can be synthesized to obtain an image having a desired blur.

“Gradation adjusting mode” refers to an exposure mode in which two exposure operations are continuously made while changing the exposure condition at a single shutter operation, thereby obtaining a captured image A whose exposure condition is adjusted to the main subject and a captured image B whose exposure condition is adjusted to the background of the main subject. In the subsequent image processing, by synthesizing these captured images A and B, it is possible to obtain an image having an appropriate density contribution throughout the entire image and an image which is strongly creative by intentionally making the contrast between the main subject and the background large.

“Super-resolution mode” refers to an exposure mode in which at least two exposure operations are continuously made without changing the focal position and the exposure condition at a single shutter operation, and a captured image A and a captured image B which are slightly differ from each other in position of the main subject within the screen are obtained due to the slight difference in camera angle between the Ath exposure and the Bth exposure. By synthesizing the captured image A and the captured image B which are slightly different in exposure position with respect to the main subject, it is possible to obtain an image which is superior in resolution to the original captured images.

<1-2. Storage Form>

The image data captured in the digital camera 1 is recorded on the memory card 11. In the normal exposure mode, the memory card 11 stores data of captured images on which compression of JPEG or the like is subjected, data of thumbnail images generated from the above image data, and tag information describing information about the captured images in the form of an image file of, for example, EXIF (Exchangeable Image File Format).

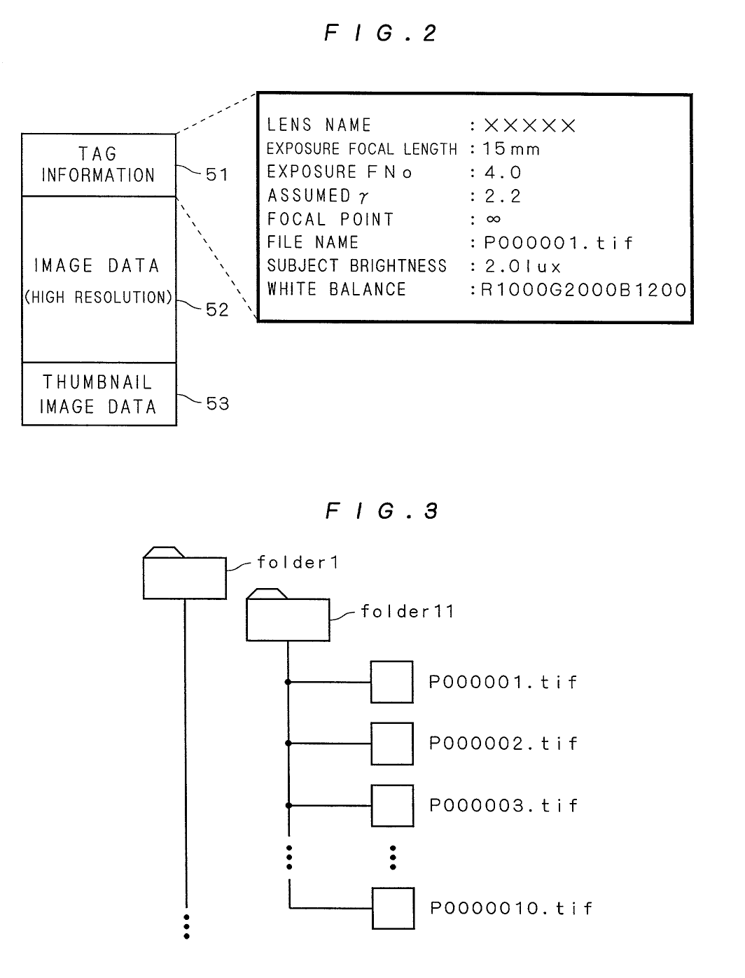

FIG. 2 shows a recording form of image file recorded on the memory card 11. The image file is divided into an additional information area 51 for storing tag information, a real image area 52 for storing data of captured image and a thumbnail image area 53 for storing data of thumbnail image.

Also, the captured images A and B captured in the above-mentioned image processing modes are, in principle, recorded on the memory card 11 in the same manner. In the real image area 52, the captured image is recorded as image data of uncompressed TIFF (Tag Image File Format) form. This is because an irreversible compression process which may deteriorate the image quality is not effected since the captured images A and B are intended for improving the image quality by being subjected to image synthesis.

Furthermore, since the captured images A and B are used for generating an image having excellent blur, gradation, resolution and the like, information which makes it recognizable that the captured image is to be used for image synthesis is included in the tag information of each image file. For both of the captured images A and B, thumbnail images are recorded.

In the tag information, information relating to exposure conditions such as exposure focal length and exposure F number, and an assumed γ value are recorded. The assumed γ value is a display characteristic of the monitor on which that image file is assumed to be displayed. For example, when a display of personal computer or the like is assumed, the γ value is assumed to be 2.2, and a γ correction in accordance with that γ value is effected.

FIG. 3 shows storage forms of each image file recorded on the memory card 11. It is preferred that the captured images A and B are stored so that the combination thereof is clear for use in the synthesis process to be conducted in the personal computer 2. For this reason, these captured images A and B are stored in the same folder. A folder 11 shown in the drawing is a folder which stores a group of image files to be subjected to the synthesis process. In the drawing, there are 10 files P000001.tif to P000010.tif of captured images to be subjected to the synthesis process. For each of these image files, noncompressed captured image data, thumbnail image data and tag information are recorded in the storage form as shown in FIG. 2, as described above.

{2. γ Correction and Linearity}

The display characteristic of a display of personal computer or the like is generally nonlinear. For example, as shown in FIG. 4, the relationship between the brightness value of input image data and the brightness value of display image exhibits a nonlinearly of γ=2.2.

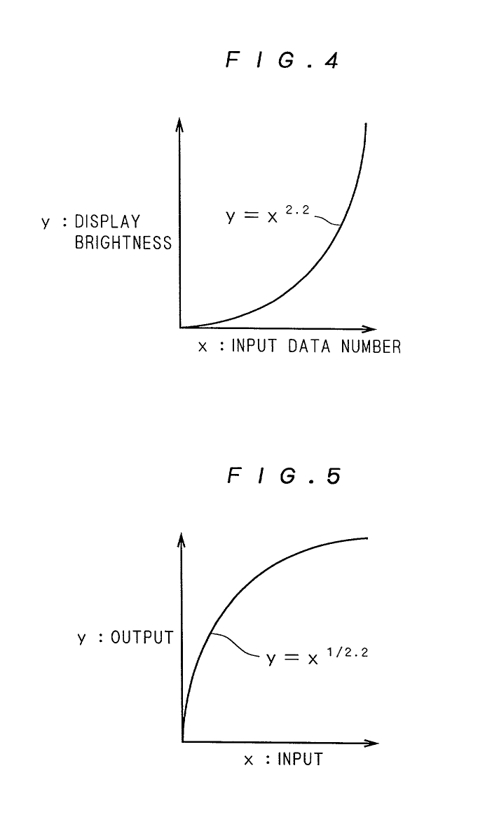

Therefore, for displaying the image file in correct color on the display, it is necessary for the image input apparatus to output an image file after effecting the γ correction on it in consideration of the display characteristic of the display. Therefore, the image input apparatus outputs the inputted image after effecting the γ correction on it as shown in FIG. 5. That is, any image file outputted from the digital camera 1 is data having been subjected to the γ correction process.

Though such data having been subjected to the γ correction secures the linearity of input/output characteristic at the time of being displayed on the display, the linearity of the data itself is not secured. If a synthesis process is conducted using such image data subjected to the γ correction as described above, the gradation characteristic will be out of order.

In view of the above, the image processing apparatus according to the present preferred embodiment makes it possible to conduct a synthesis process while keeping the gradation characteristic normal as will be described below.

{3. Configuration of Image Processing Apparatus}

Next, a configuration of the image processing apparatus will be explained. In the present preferred embodiment, the image processing apparatus is configured by the personal computer 2, an image processing program 65 installed into the personal computer 2 and the like.

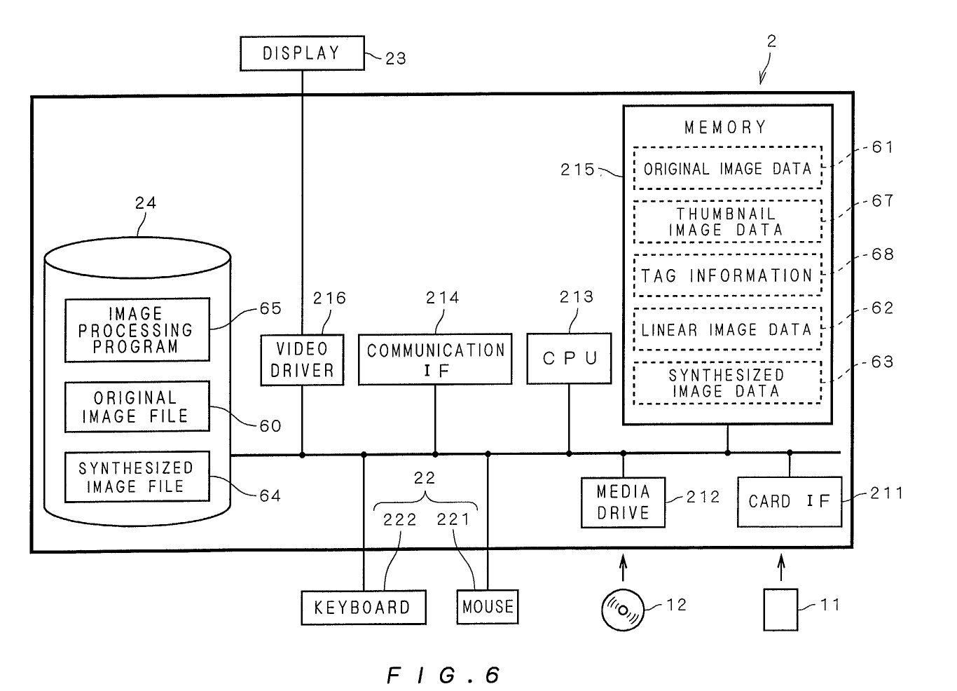

As shown in FIGS. 1 and 6, to the personal computer 2 are connected an operational part 22 configured by a mouse 221, a keyboard 222 and the like, and a display 23. The main body of the personal computer 2 has a CPU 213, a memory 215, a video driver 216, a hard disk 24 and the like, and in the hard disk 24 is stored the image processing program 65. Furthermore, by controlling the video driver 216, an image file or the like is displayed on the display 23.

Furthermore, the personal computer 2 is equipped with a card IF 211 and a communication IF 214 serving as interfaces with the external. A program operative in the CPU 213 can read the data in the memory card 11 via the card IF 211, and can communicate with the external via the communication IF 214. The communication IF 214 includes a USB interface, a LAN interface and the like.

Further, the personal computer 2 has a recording media drive 212 and can access to a medium 12 such as CD-ROM or DVD-ROM inserted into the recording media drive 212.

The image processing program 65 according to the present preferred embodiment may be provided via the medium 12 or may be provided via the communication IF 214 from a server on the INTERNET or LAN.

{4. Super-resolution Process}

<4-1 Process Flow by File Selection}

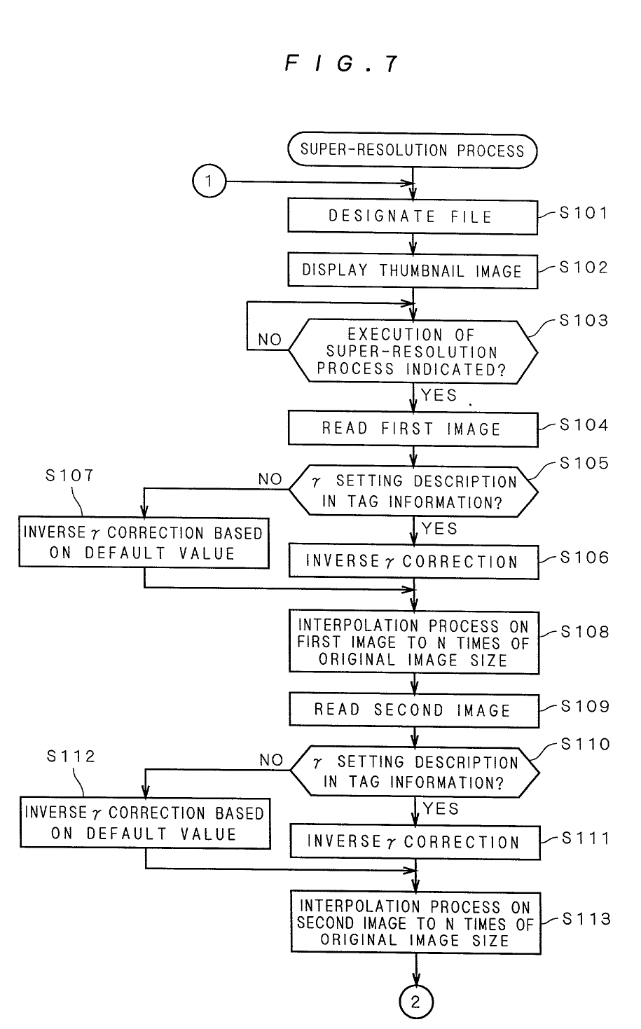

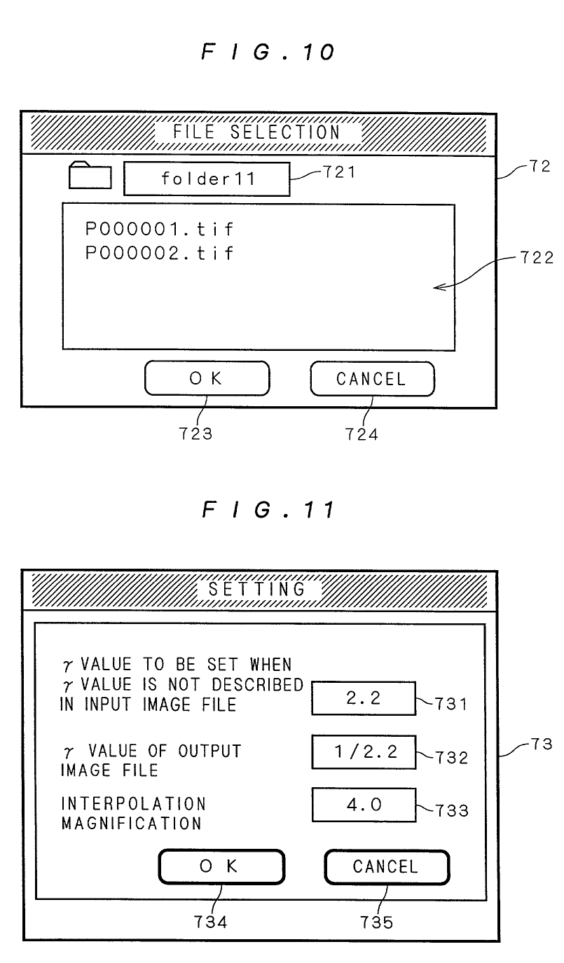

Next, the contents of processes of the image processing program 65 will be explained while referring to FIGS. 7 to 15. In the following explanation, explanation will be made while exemplifying the case where the image file to be subjected to the synthesis process is an image file captured in the “super-resolution mode” in the digital camera 1 and a super-resolution process is conducted by executing the image processing program 65.

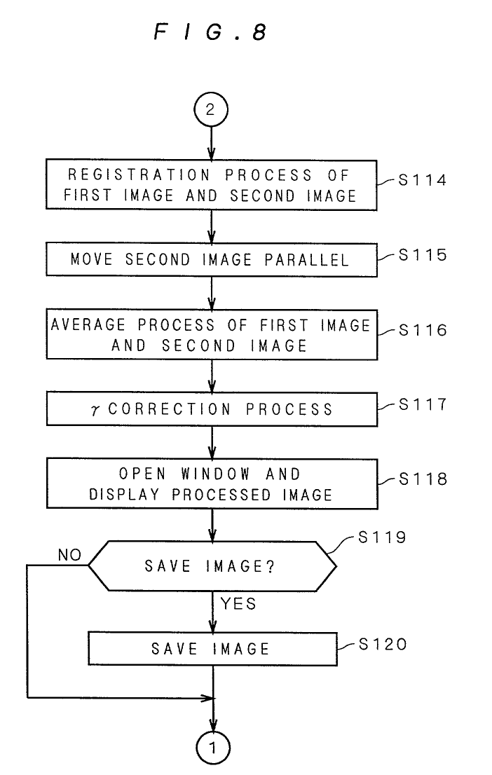

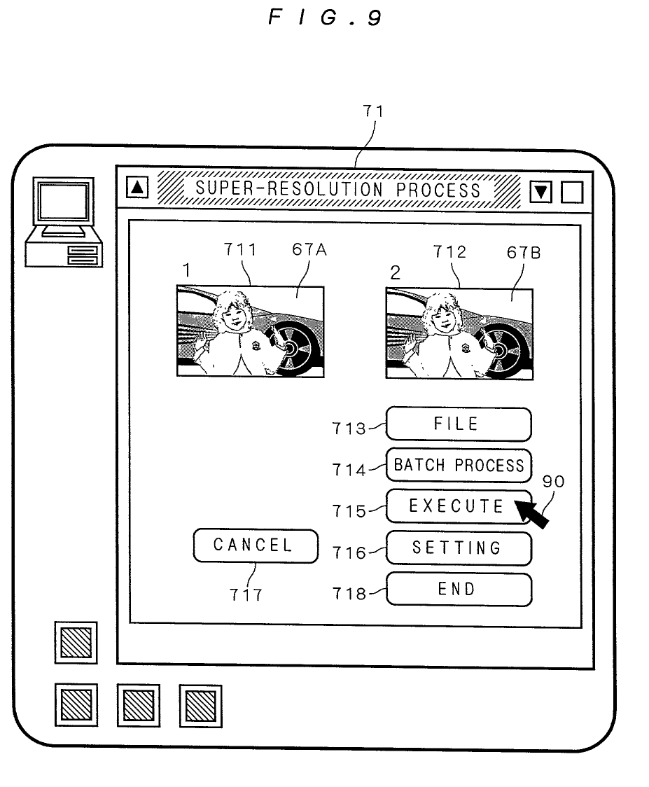

First, a super-resolution process will be explained with the use of the flowcharts of FIGS. 7 and 8. An operator makes a predetermined operation using the operational part 22 to activate the image processing program 65. As a result of this, for example, an image processing menu is displayed on the display 23. The image processing menu shows a list of process menu such as “blur adjusting process”, “gradation adjusting process”, “super-resolution process” and the like. Furthermore, the operator makes a predetermined operation to select the “super-resolution process”, as a result of which a super-resolution process screen 71 is displayed on the display 23, as shown in FIG. 9.

Next, the operator selects a file button 713. Selection of the button is made by issuing a selecting designation after moving a cursor 90 onto the file button 713 by operating the mouse 221.

Upon selection of the file button 713, a file designating screen 72 is displayed. The file designating screen 72 is a screen on which an original image file 60 accumulated in the hard disk 24 is to be designated.

In this context, the original image file 60 refers to an image file captured in the image processing mode at the digital camera 1 (above-mentioned captured images A and B). The original image file 60 outputted at the digital camera 1 is stored in the hard disk 24 using the memory card 11 or the communication IF 214 as described above.

The operator designates a folder name in which the original image file 60 is stored on a folder designating area 721, and then a list of files in the designated folder is displayed in a file display area 722. In this context, a process for two original image files P000001.tif and P000002.tif in the folder 11 will be shown as an example.

The operator individually designates a file name to be designated by operating the mouse 221 or the like and selects an OK button 723. As a result of this, the file designating operation is completed. For canceling the operation, a cancel button 724 can be selected.

When these two original image files 60 are designated by the operator operating the mouse 221 or the like, the designated original image files 60 are read into memory 215 from the hard disk 24 in response to that designation operation (step S101). In this context, it is contemplated that two image files of original image files 60A and 60B are designated.

As a result of this, original image data 61A, 61B stored in the respective real image area 52, thumbnail images 67A, 67B stored in the respective thumbnail image area 53, and tag information 68A, 68B stored in the respective tag information area 51 of the respective original image files 60A and 60B are read into the memory 215. In FIG. 6, the original image data 61A, 61B is depicted as the original image data 61, the thumbnail images 67A, 67B are depicted as the thumbnail data 67, and the tag information 68A, 68B is depicted as the tag information 68.

Next, the thumbnail image data 67A, 67B thus read is displayed on thumbnail image display areas 711, 712 of the super-resolution process screen 71 (step S102). FIG. 9 shows the condition in which two thumbnail image data 67A, 67B is displayed. The displayed images are actually two images which are slightly different in angle.

Under this condition, the image processing program 65 is in standby condition of the super-resolution process (step S103). Then, as the operator selects an execute button 715 by operating the mouse 221 or the like, it is determined that an instruction for executing the super-resolution process is made (Yes in step S103), and the first original image data 61A is read (step S104), thereby starting the super-resolution process.

Various setting operations may be made prior to execution of the super-resolution process. The operator selects a setting button 716, and a setting screen 73 as shown in FIG. 11 is displayed. As will be described later, it is possible to change setting values such as γ value and interpolation magnification on this screen.

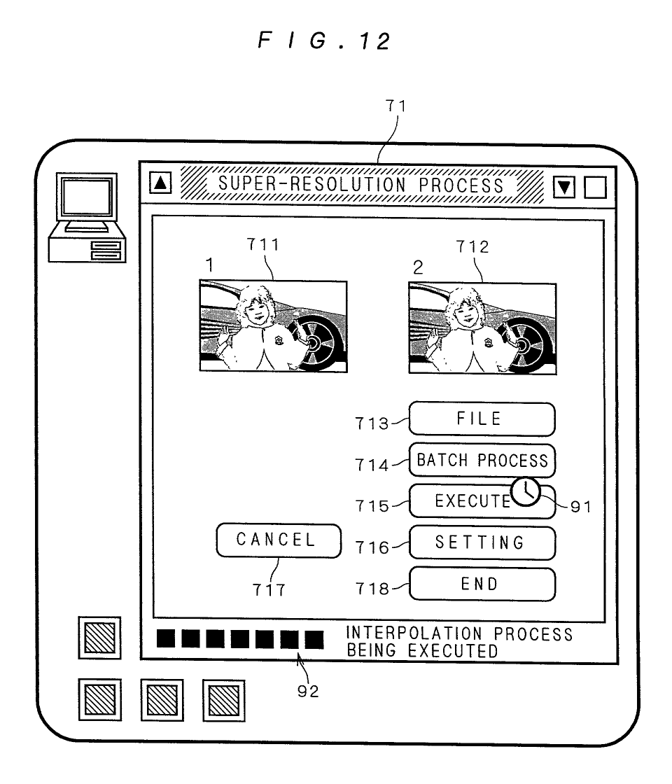

As the execution of the super-resolution process starts, as shown in FIG. 12, the cursor 90 turns to a clock display 91 to indicate that execution condition comes into effective, while a progress bar 92 is displayed to visually display the progression of the execution. When it is desired to cancel the execution, the super-resolution process can be cancelled by selecting a cancel button 717.

Next, whether or not there is a description of γ setting value is determined with reference to the tag information 68A of the original image file 60A (step S105). In this context, the γ setting value refers to an assumed γ value described in FIG. 2, and will be information for determining what kind of γ correction was effected when the original image data 61A is captured by the digital camera 1.

In the case where an assumed γ value is recorded in the tag information of the original image data 61A (Yes in step S105), a gradation conversion using the same γ value as the assumed γ value is performed on that original image data 61A (step S106). This process is called an inverse γ correction process.

For example, in the case where the assumed γ value is 2.2, a γ correction process of γ=1/2.2=0.455 is effected on the image data in the digital camera 1. Therefore, by subjecting the image data that has been subjected to such a γ correction process to the inverse γ correction process of γ=2.2, the linearity of the image data is secured.

Furthermore, the inverse γ correction process improves the number of bits of output image data with respect to the input image data. For example, in the case where the original image data 61 is 8-bit image data, by performing the inverse γ correction process, the image data thus outputted will be 10-bit image data.

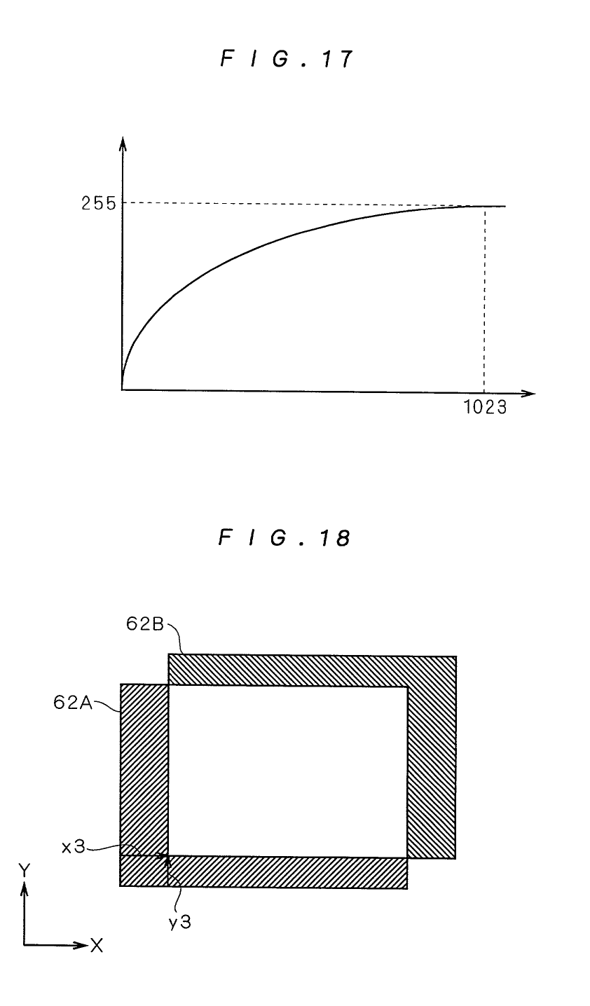

Image data captured by a digital camera is outputted from the CCD of the digital camera in the form of, for example, 10-bit image data. Also, the digital camera effects the γ correction on the 10-bit image data to output 8-bit image data. FIG. 17 shows a γ function in which the horizontal axis represents input data before γ correction, and the vertical axis represents output data after γ correction. That is, the γ correction is conducted so that the maximum brightness (1023) of the input data is converted into the maximum brightness (255) after γ correction.

Therefore, in the inverse γ correction process, conversion such that the vertical axis represents input data before inverse γ correction, and the horizontal axis represents output data after inverse γ correction in FIG. 17 is conducted.

By converting the 8-bit image data to the 10-bit image data, a gradation area which is no longer used exists just after the conversion. However, in the case where average process of pixel values among plurality of 10-bit image data is conducted in the subsequent synthesis process, there arises the case that such unused gradation area is used. Therefore, it will be an effective process from the view point of generating a synthesized image. In the following description, the inverse correction process in any case refers to a process which increases the number of bits of gradation.

In the case where an assumed γ value is not recorded in the tag information 68A of the original image data 61A (No in step S105), the inverse γ correction process is performed while regarding the default γ value as an assumed γ value (step S107). The input area 731 in the setting screen 73 shown in FIG. 11 is an input form of default γ value, and for example, in the drawing, the default γ value is set to be 2.2. Furthermore, the input area 732 displays the value representing in what manner the γ correction is made for the setting value of the default γ value. The operator can arbitrarily change the default γ value by inputting the numerical value on this input area 731. For changing the default γ value, a desired value is inputted in the input area 731 and the OK button 734 is selected. Furthermore, for canceling the process, the cancel button 735 can be selected.

The inverse γ correction process is performed in step S106 or step S107, and then an interpolation process is effected on the first original image data 61A to multiply the size of it to n times the size of the original image.

Now, the interpolation process will be explained. The super-resolution process is a process for obtaining an image of high resolution by synthesizing the original image data 61A and 61B that are slightly displaced from each other in exposure position due to the slight difference in camera angle.

In this connection, it is necessary to synthesize the original image data 61A and 61B while performing registration on the both image data in synthesizing the original image data 61A and 61B that are slightly displaced from each other in exposure position. In this registration process, the higher the resolutions of the original image data 61A and 61B, the higher accuracy the registration can be achieved.

For this reason, prior to the synthesis process, with respect to the original image data 61A and 61B, the interpolation process is conducted to increase the resolutions of the respective image data, and thereafter the registration process is conducted.

As the interpolation process, well-known methods such as cubic convolution method, quadratic spline method, integrating resampler method exist, and there is no limitation for which method is to be used. Furthermore, in the setting screen 73 shown in FIG. 11, the operator can arbitrarily set the interpolation magnification. The operator input a numerical value in the interpolation magnification input area 733 by operating the keyboard 222 or the like, thereby setting the interpolation magnification. The drawing shows the condition that the interpolation magnification value is set to be 4.0 in the interpolation magnification input area 733. Furthermore, the above other interpolation methods (cubic convolution method and the like) may be selected.

Referring the flow chart of FIG. 7 again, explanation will be continued. The pixel data is interpolated in accordance with the set interpolation magnification (n times) in step S108, and the original image data 61A is written to the memory 215 as the linear image data 62A.

Next, the second original image data 61B is read (step S109). Also with respect to the original image data 61B, in the same manner as described above, first whether or not an assumed γ value is set in the tag information 68B is determined (step S110), and in the case where an assumed γ value is set, an inverse γ correction process is performed based on the assumed γ value (step S111). To the contrary, in the case where an assumed γ value is not set, an inverse γ correction process based on the default γ value is performed (step S112).

Next, also for the original image data 61B, in the same manner as described above, an interpolation process is performed to multiply the image size to n times the original size (step S113). In the interpolation process of steps S108, S113, it is assumed that the original image data 61A, 61B are multiplied to four times the original size by interpolating a new pixel between each pixel. The pixel data of the original image data 61B is interpolated in this manner, and it is written into the memory 215 as linear image data 62B. In FIG. 6, the linear image data 62A and 62B are generally called as linear image data 62.

The inverse γ correction process is performed in this way, and two linear image data 62A and 62B having linearity and having been subjected to the interpolation process is written into the memory 215.

Next, a registration process of the linear image data 62A and 62B are performed as shown in FIG. 8 (step S114). The registration process refers to a process for determining a positional deviation between both images to be synthesized.

Now, a method for performing registration of the linear image data 62A and the linear image data 62B will be explained. The registration is performed to determine a movement amount by which the correlative coefficient C (ξ, η) shown by the expression 1 becomes minimum while moving the linear image data 62B in parallel in the X direction and Y direction.

C(ξ, η)=ΣΣ{P1(x, y)−P2(x−ξ, y−η)}² [Expression 1]

In the above expression 1, x, y represent coordinate variables in the rectangular XY plane coordinate system whose origin is the center of the image, P1(x, y) represents levels of image data at the coordinate points (x, y) of the linear image data 62A, and P2(x−ξ, y−η) represents levels of image data at the coordinate points (x−ξ, y−η) of the linear image data 62B. That is, the correlative coefficient C (ξ, η) expressed by the Expression 1 is obtained by squaring a difference in level between corresponding image data of two images, and calculating a total sum of the resultant values for all pixel data. And, while a set of (ξ, η) which represents movement amount of the linear image data 62B is changed, the set of (ξ, η) at which the correlative coefficient C becomes minimum is a movement amount of the linear image data 62B when the both images are best matched.

In the present preferred embodiment, the set of (ξ, η) at which the correlative coefficient C becomes minimum is calculated as (x3, y3), for example, by changing ξ representing movement amount regarding the X coordinate of the linear image data 62B from −80 to +80, and η representing movement amount regarding the Y coordinate of the linear image data 62B from −60 to +60. The movement amount ±80±60 of X, Y man be arbitrarily set in accordance with the image size and assumed amount of deviation.

Furthermore, in this registration process, only the G color component that exerts large influence on resolution from view point of the human visual characteristic may be used. In such a case, as for the R, B color components which exert a little influence on the resolution from the view point of the human visual characteristic, registration processes can be simplified by utilizing the movement amount calculated for the G color component.

Then, the linear image data 62B is moved in parallel based on the deviation amount determined in step S114, and the positions of the linear image data 62B and the linear image data 62A are registered (step S115). Then, the parts of the respective image data that are not overlapped after parallel movement are deleted. In this way, the parts that are not overlapped and hence are not required for image synthesis (the part indicated by hatching in FIG. 18) are deleted, and only the image data that is required for image synthesis to which correct registration has been effected is acquired.

Next, by subjecting the linear image data 62A and the linear image data 62B to the average process, a new synthesized image data 63 is generated (step S116). In this context, the term “average process” refers to a process of calculating an average of brightness in the same coordinate position of the linear image data 62A, 62B that have been subjected to the registration, and generating a new image whose pixel value is this average brightness.

Through the above processes, one synthesized image data 63 is generated from the original image files 60A and 60B. In this synthesis process, since the original image data 61A and 61B are synthesized after being modified to the linear images through the inverse γ correction process, the gradation characteristic will not become out of order.

Next, a γ correction is effected on the synthesized image data 63 in consideration of displaying the synthesized imaged on the monitor (step S117). This γ correction process is performed on the basis of the assumed γ value included in the tag information 68 of the original image file 60.

When the assumed γ value included in the tag information 68 of the original image file 60A (or 60B) is 2.2, the original image data 60A and 60B has been subjected to the γ correction process of γ=1/2.2, respectively in the digital camera 1. And, the original image data 61A and 61B is subjected to the inverse γ correction process of γ=1/2.2, in steps S106, S111, respectively, and thus by performing the γ correction process of γ=1/2.2 again on the synthesized image data 63, it returns to the image data conforming to the gradation characteristic of the monitor.

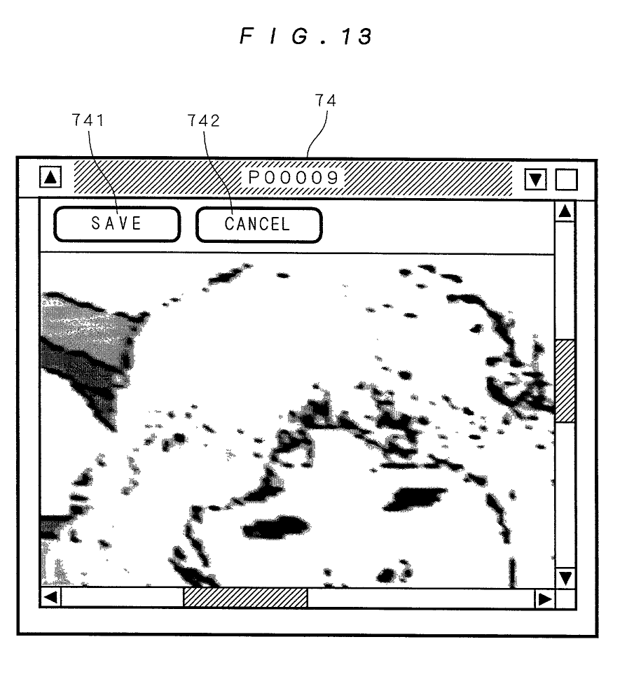

The γ correction process is performed, and a result displaying screen 74 is displayed as shown in FIG. 13 (step S118), so that the operator can check the generated synthesized image on the display 23.

As the synthesized image display window 74 is displayed, it enters a waiting state for image saving (step S119). In this state, if the operator selects a save button 741 provided in the result display screen 74 by an operation of the mouse 221 or the like, it is determined that a designation for saving an image is made (Yes in step S119), a synthesized image file 64 which consists of the synthesized image data 63, a thumbnail image generated from the synthesized image data 63, and tag information is generated and stored in the hard disk 24.

Upon completion of the image saving process, the flow returns to the display state of the super-resolution screen 71 shown in FIG. 9 again. Also, if the operator selects the cancel button 742 in the condition that the synthesized image data 63 is displayed in the result display screen 74, the linear image data 62 and the synthesized image data 63 temporarily stored in the memory 215 is deleted and the flow returns to the state shown in FIG. 9 again.

In this manner, the synthesized image data 63 thus stored in the hard disk 24 has a higher resolution than the original image by synthesizing the two original image data 61A and 61B captured with slightly different camera angles. Furthermore, since the inverse γ correction process is effected on the two original image data 61A and 61B and the synthesis process is performed after modifying the imaged data to have linearity in the gradation characteristic, it is possible to obtain a synthesized image having a high resolution and excellent image quality without causing a distortion in gradation characteristic during the adding process.

In the above, the explanation was made while exemplifying the case where the “super-resolution process” is executed with respect to the image file captured in the “super-resolution mode”, however, the same applies also to the cases where the “blur adjusting process” and the “gradation adjusting process” are executed on the image file captured in the “blur adjusting mode” and the “gradation adjusting mode”, respectively. Though the respective image processings are different in object from each other, in any case, by performing the operational process after effecting the inverse γ correction on the original image data as same as the above-described process flow, it is possible to obtain a synthesized image having a high image quality without causing a distortion in gradation characteristic.

<4-2 Batch Process Flow by Folder Selection>

Next, a batch process flow will be explained. The super-resolution process described in the above <4-1> starts from individually designating a plurality of original image files in step S101. In the batch process flow, by designating a folder, the necessity of designating individual files is eliminated, and a batch process is realized.

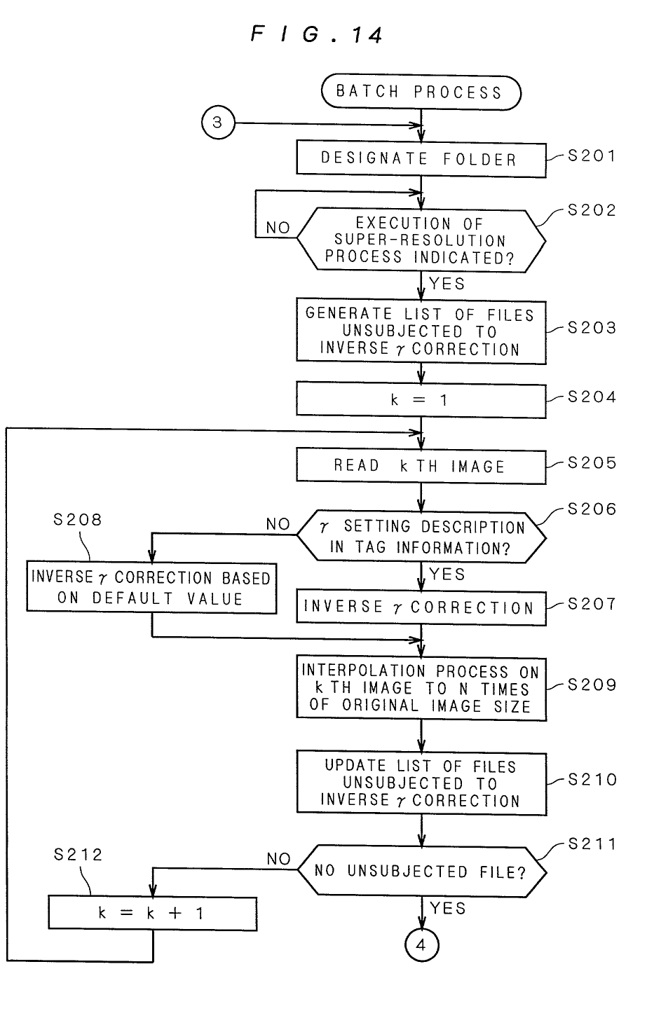

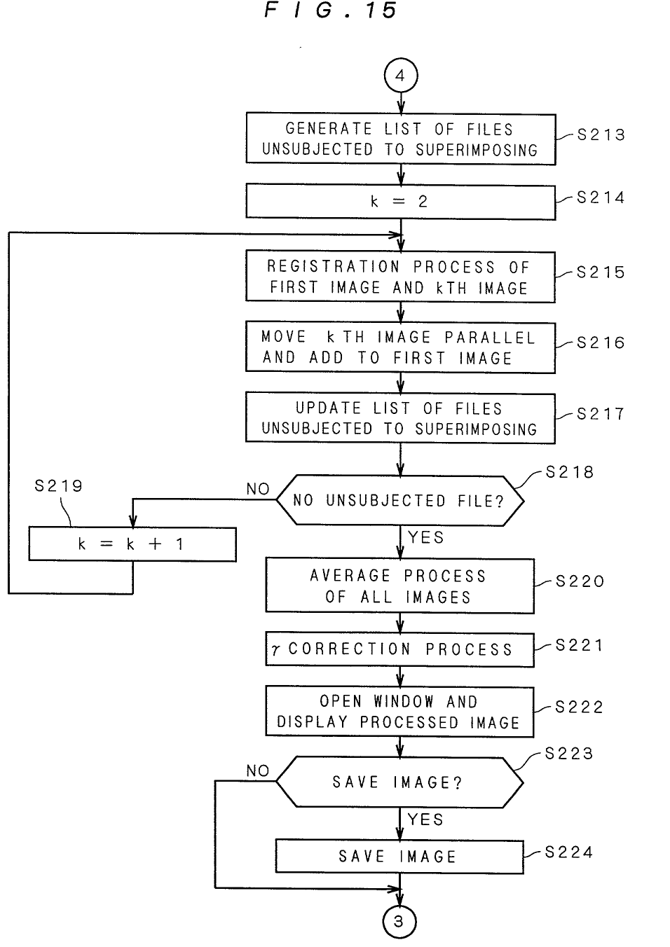

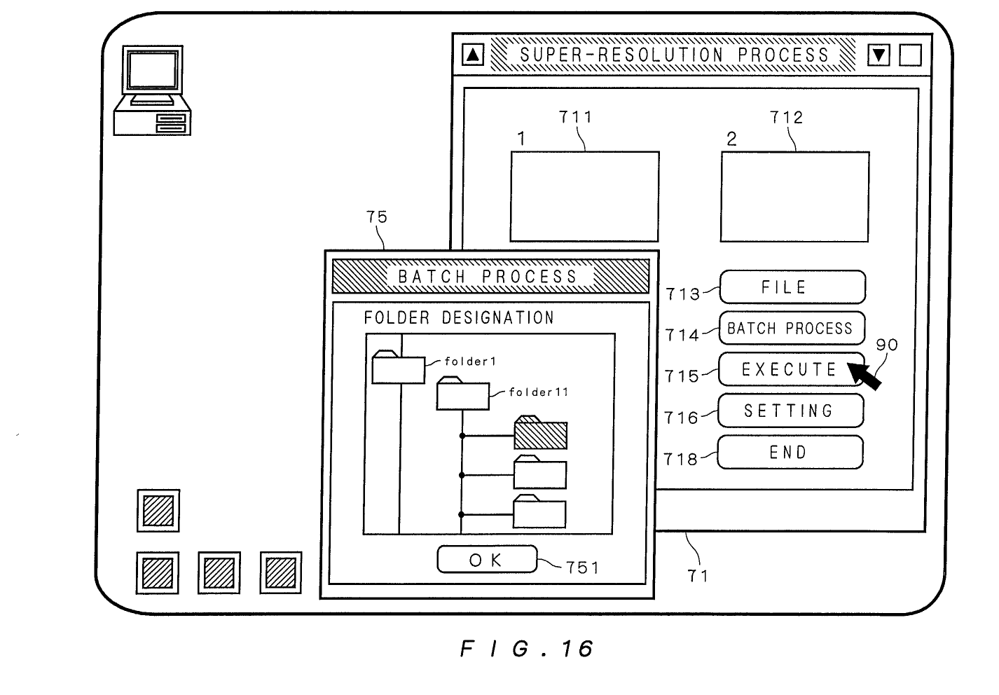

A batch process flow will be explained while referring to the flow charts of FIGS. 14 and 15. In the state that super-resolution process screen 71 shown in FIG. 9 is displayed, the operator selects a batch process button 714 by operating the mouse 221 or the like. As a result of this, a folder designating screen 75 is displayed as shown in FIG. 16.

Then, the operator operates the mouse 221 or the like to search the location of the original image file 60 stored in the hierarchical structure in the hard disk 24 and designates a specified folder. In this description, the explanation will be made while taking the case where the operator selects a folder 11 in the folder configuration as shown in FIG. 3 as an example.

As the folder 11 is selected by the operator, the image processing program 65 designates all files stored in the folder 11 (step S201). Then, the folder designating screen 75 ends, and the super-resolution process screen 71 is activated again to enter a waiting state for designation of super-resolution process (step S202).

Then, the operator selects the execute button 715, and it is determined that a designation for super-resolution process was made (Yes in step S202), and subsequently a list of files unsubjected to inverse γ correction is generated (step S203).

In the initial state, file names of all the selected original image files 60 are listed in the list of files unsubjected to inverse γ correction. That is, in this example, 10 file names of P00000.tif to P000010.tif are listed.

Next, the image processing program 65 set the counter K of the repetitive process at 1 (step S204). This counter k corresponds to the number which is sequentially assigned to the 10 files of P000001.tif to P000010.tif.

Then, the kth original image file 60 (P000001.tif at k=1) is read (step S205), whether or not an assumed γ value is set in the tag information 68 is determined (step S206), and if an assumed γ value is set (Yes in step S206), an inverse γ correction process based on the assumed γ value is conducted (step S207). On the other hand, if an assumed γ value is not set (No in step S206), an inverse correction process is conducted based on a default γ value (step S208).

Furthermore, an interpolation process is effected on the kth (first) original image data 61 to interpolate the pixel data (step S209). The original image data 61 to which the inverse γ correction process and the interpolation process have been effected as described above is stored as the linear image data 62, the name of the kth (first) original image file (P000001.tif) is deleted from the list of files unsubjected to inverse γ correction, and the list is updated (step S210).

Then, whether or not unprocessed files remain in the list of files unsubjected to inverse γ correction is determined (step S211), and if there remains a unprocessed file (No in step S211), the counter k is incremented by 1 (step S212), the flow returns to step S205, and the inverse γ correction process and interpolation process are effected on the k+1th (second) original image file (P000002.tif) in the same manner as described above.

The above process is repeated and the processes up to the 10th original image file (P000010.tif) have completed, and then it is determined that there are no unprocessed files left (Yes in Step S211), the repetitive process ends, and the flow proceeds to the next step.

Next, the image processing program 65 generates a list of files unsubjected to superimposing (step S213). In the initial state, the list of files unsubjected to superimposing shows file names of all the original image files 60 having been subjected to the inverse γ correction process. That is, in this case, ten file names of P000001.tif to P000010.tif are listed.

Next, the image processing program set the counter k of the repetitive process at 2 (step S214), and performs a registration process on the first linear image data 62 and the kth (second) linear image data 62 (step S215). Then, the kth (second) linear image data 62 is moved in parallel, and the kth (second) linear image data 62 is added to the first linear image data 62 (step S216). “Adding process” refers to a process of adding brightness of the respective coordinate position of both linear image data having been subjected to registration to make the added brightness as a new pixel value of the first linear image data 62.

Upon completion of the adding process, the file name (P000002.tif) of the kth (second) original image file is deleted from the list of files unsubjected to superimposing process and the list is updated (step S217).

Then, whether or not unsubjected files remain in the list of unsubjected to superimposing process is determined (step S218), and if there is an unsubjected file left (No in step S218), the k is incremented by 1 (step S219), and again in step S215, a registration process of the first linear image data 62 and the third linear image data 62 is effected and an adding process is conducted (steps S215, S216). In this context, since pixel values of the second linear image data 62 are added to the first linear image data 62 in the first process of the repetitive processes, the first to the third linear image data 62 is subjected to adding process in the second process of the repetitive processes.

When unsubjected files are no longer left in the list of files unsubjected to superimposing process by conducting such processes up to the 10th linear image data 62 (Yes in step S218), an average process is conducted on each pixel value of the first linear image data 62 to which all of the first to the tenth linear image data has been added (step S220). In this example, since ten pixel image data 62 is added, by dividing each of the pixel values of the added image data by 10, a synthesized image data 63 is generated.

Next, a γ correction process is performed on the synthesized image data 63 (step S221), and the synthesized image data 63 is displayed as shown in FIG. 13 (step S222). When the operator selects the save button 741, it is determined that saving of image is designated (Yes in Step S223), and the synthesized image file 64 is generated while thumbnail image data and tag information are added to the synthesized image data 63, and the synthesized image file 64 is saved in the hard disk 24 (step S224).

When the operator selects the cancel button 742 (No in step S223), the linear image data and the synthesized image data that are temporarily stored in the memory 214 are deleted and the flow returns to the super-resolution process screen 71 again.

In the same manner as described above, it is possible to generate a synthesized image of high resolution and high quality, and moreover in the case of the batch process, it is possible to achieve the synthesis process without requiring troublesome operations because it is not necessary to designate individual original image files that are to be synthesized.

Furthermore also in the blur adjusting process and the gradation adjusting process, by performing the batch process in the same manner as described above, it is possible to obtain a synthesized image having excellent image quality while improving the operability.

While the invention has been shown and described in detail, the foregoing description is in all aspects illustrative and not restrictive. It is therefore understood that numerous modifications and variations can be devised without departing from the scope of the invention.

What is claimed is:

1. An image processing apparatus comprising:
a memory for storing a plurality of image data that have been subjected to a γ correction;
a reader for reading the plurality of image data stored in said memory;
a first generator for generating, with respect to each image data read by said reader, image data that have been subjected to a γ correction having a characteristic which is inverse to the γ correction effected on each image data; and
a second generator for generating synthesized image data resulting from synthesizing a plurality of image data that have been generated by said first generator.

2. The image processing apparatus according to claim 1, wherein the image data generated by said first generator is linear image data.

3. The image processing apparatus according to claim 2, wherein said second generator performs an image processing including adding among a plurality of linear image data.

4. The image processing apparatus according to claim 1, said image processing apparatus further comprising:
a gamma corrector for performing a γ correction, in accordance with a display characteristic of an image display device, on the synthesized image data generated by said second generator.

5. A program product in which a program which enables a data processing apparatus to execute a processing is recorded, the processing comprising the steps of:
(a) reading a plurality of image data having been subjected to γ correction;
(b) generating, with respect to each of the read image data, image data that have been subjected to a γ correction having a characteristic which is inverse to the γ correction effected on each of the read image data; and
(c) generating synthesized image data resulting from synthesizing said generated plurality of image data.

6. The program product according to claim 5, wherein
said program product enables the further process of:
performing a γ correction on said generated synthesized image data and generating image data in accordance with a display characteristic of an image display device.

7. The program product according to claim 5, wherein
said step (b) generates linear image data for each of the read image data.

8. The program product according to claim 7, wherein
said step (c) includes the step of performing matching process between a plurality of linear image data.

9. The program product according to claim 7, wherein
the γ correction process executed in said step (b) increases the number of gradation bits of said linear image data compared to that of the image data read in said step (a).

10. The program product according to claim 7, wherein
said program product enables the further process of:
performing an interpolation process of pixel with respect to each linear image data generated in said step (b).

11. The program product according to claim 5, wherein
the process of said step (b) further comprises the process of:
reading information regarding the γ correction that has been effected on said read image data from information associated with the image data read in step (a); and
calculating a setting value of said γ correction having an inverse characteristic on the basis of said information regarding the γ correction.

12. The program product according to claim 11, wherein
the process of said step (b) further comprises the process of:
performing a γ correction in accordance with a predetermined setting value when said information regarding the γ correction that has been effected on said read image data is not read from information associated with the image data read in step (a).
